(19) United States
(12) Patent Application Publication
(10) Pub. No.: US 2013/0058042 A1
(43) Pub. Date: Mar. 7, 2013

(54) Laminated heat sinks

(71) Applicants: Todd Richard Salamon, New Providence, NJ (US); David Andrew Ramsey, Maplewood, NJ (US)

(72) Inventors: Todd Richard Salamon, New Providence, NJ (US); David Andrew Ramsey, Maplewood, NJ (US)

(21) Appl. No.: 13/199,565

(22) Filed: Sep. 3, 2011

(51) Int. Cl. H05K 7/20; B23P 11/00; F28F 7/00

(52) U.S. Cl. 361/700; 361/704; 361/720; 165/185; 29/428

(57) ABSTRACT

An apparatus includes a heat sink with a complex 3D structure. The heat sink includes a stack of metal layers. The metal layers are mechanically connected together and being separated by physical interface regions. The stack has array of channels for carrying fluid through the stack. Each channel of the array has a lateral surface formed by portions of more than one of the metal layers.

### BACKGROUND

1. Technical Field

The invention relates to heat sinks, methods of making heat sinks, and apparatus including heat sinks.

2. Related Art

This section introduces aspects that may help facilitate a better understanding of the inventions. Accordingly, the statements of this section are to be read in this light and are not to be understood as admissions about what is prior art or what is not prior art.

Many active electronic components and active optical components internally generate heat, which is dissipated so that the components can operate at a desired temperature and/or so that the components will continue to operate over a desired lifetime. An inability to adequately dissipate the internally generated heat can limit capacities and/or functionalities of such components and/or can result in the premature failure of such components. Often, the dissipation of heat produced by such active components involves using air as a medium to transport the heat away. For example, a heat sink may be attached to a heat producing component, and a flow of air past the heat sink will provide the cooling that primarily dissipates the heat from the heat sink.

Some heat sinks are constructed with large and/or specialized surfaces that improve the transfer of heat to coolant air. Unfortunately, such heat sinks may have a large physical form factor that can interfere with the circulation of air thereby interfering with the overall dissipation of heat from such an active component and/or from a circuit board holding such an active component.

Some heat sinks have channels that direct the flow of air to improve the transfer to heat to the air. One such heat sink includes an array of parallel fins that both directs the flow of air and adds more surface area for transferring heat from the heat sink to the air. Other such heat sinks include channels that have walls on all lateral sides.

### SUMMARY

Some embodiments provide an apparatus that includes a heat sink with a complex 3D structure. The heat sink has a stack of metal layers. The metal layers are mechanically connected together and are separated by physical interface regions. The stack has an array of channels for carrying a fluid through the stack. Each channel of the array has a lateral surface formed by portions of more than one of the metal layers.

In some embodiments of the above apparatus, each channel of the array may include a segment in the physical interface region between a pair of the metal layers of the stack.

In some embodiments of any of the above apparatus, some of the metal layers may include openings that interconnect pairs of the channels.

In some embodiments of any of the above apparatus, some of the metal layers of the stack may be brazed, welded, or soldered together.

In some embodiments of any of the above apparatus, the apparatus may further include thermally conductive grease located between neighboring ones of the metal layers.

In some embodiments of any of the above apparatus, the apparatus may further include a heat pipe, wherein a segment of the heat pipe is located in one of the channels.

In some embodiments, any of the above apparatus may further include an electronic or optical component configured to internally produce heat during operation. In such embodiments, a first surface of the heat sink faces and is in thermal contact with a portion of a second surface of the electronic or optical component. In any embodiments of this paragraph, the metal layers may be stacked along a direction substantially normal to the portion of the second surface. In any embodiments of this paragraph, some of the metal layers may include openings that interconnect pairs of the channels. In any embodiments of this paragraph, some of the metal layers of the stack may be brazed, welded, or soldered together. In any embodiments of this paragraph, the apparatus may further include a circuit board, wherein the electronic or optical component is mechanically fixed to the circuit board. In any embodiments of this paragraph, the apparatus may further include a one or more heat pipes or a vapor chamber located between the electronic or optical component and the heat sink. In any embodiments of this paragraph, the apparatus may further include a heat pipe, wherein a segment of the heat pipe is located in one of the channels.

Other embodiment provides a method of fabrication of a heat sink with a complex 3D structure. The method includes providing a plurality of metal layers and stacking the metal layers to form a stack of the heat sink. The stack has physical interface regions between the metal layers and has an array of channels for carrying a fluid through the stack formed by the metal layers. Each channel of the array has a lateral surface formed by portions of more than one of the metal layers.

In some embodiments of the above method, each channel may include a segment in the physical interface region between a pair of the metal layers of the stack.

In some embodiments any of the above methods, some of the provided metal layers include openings, wherein each opening interconnects a pair of the channels in the heat sink.

In any above method, the method may further include mechanically and thermally joining the heat sink to a portion of a surface of an electronic or optical component such that the heat sink forms a segment of a primary path for dissipating heat internally generated by the electronic or optical component during operation thereof. In any embodiments of this paragraph, the joining may cause the metal layers to be stacked along a direction substantially normal to the portion of the surface of the electronic or optical component. In any embodiments of this paragraph, the method may further include a circuit board, wherein the electronic or optical component is mechanically fixed to the circuit board. In any embodiments of this paragraph, the mechanically and thermally joining may include fixing one or more heat pipes or a vapor chamber between the heat sink and the portion of the surface of the electronic or optical component.

### BRIEF DESCRIPTION OF THE DRAWINGS

FIGS. 1A-1D are end views schematically illustrating a heat-producing element and embodiments of heat sinks having complex three-dimensional (3D) structures;

FIG. 2A is an end view illustrating a laminated heat sink with a honeycomb structure, e.g., specific embodiments of the heat sinks of any of FIGS. 1A-1C;

FIG. 2B is an oblique view illustrating a laminated heat sink with a Schwarz-P structure, e.g., specific embodiments of the heat sinks of any of FIGS. 1A-1C;

FIG. 2C is an end view illustrating a laminated heat sink with a foam-like structure, e.g., specific embodiments of the heat sinks of FIGS. 1A-1C;

FIG. 3 is an oblique view illustrating one layer of the heat sink of FIG. 2A; and

FIG. 4 is a flow chart illustrating a method of making a heat sink with a complex 3D structure, e.g., the heat sinks of FIGS. 1A, 1B, 1C, 2A, 2B, and 2C.

In the Figures and text, similar or like reference symbols indicate elements with similar or the same functions and/or structures.

In the Figures, the relative dimensions of some features may be exaggerated to more clearly illustrate one or more of the structures or features therein.

Herein, various embodiments are described more fully by the Figures and the Detailed Description of Illustrative Embodiments. Nevertheless, the inventions may be embodied in various forms and are not limited to the embodiments described in the Figures and Detailed Description of Illustrative Embodiments.

### DETAILED DESCRIPTION OF ILLUSTRATIVE EMBODIMENTS

U.S. Patent Application Publication No. 2009/0321045 is incorporated herein by reference in its entirety.

The thermal resistance is a physical property of a heat sink positioned to transport heat away from a heat-producing component. The thermal resistance is given by:

R_{heat sink}=(T_{component}−T_{inlet fluid})/Q_{component}.

Here, T_{component} is the component's temperature, T_{inlet fluid} is the temperature of the fluid input to cool the heat sink, and Q_{component} is the heat power produced by the heat-producing component. Thus, for a given heat power, Q_{component}, a smaller thermal resistance, R_{heat sink}, implies that the difference between the temperature, T_{component}, of the heat-producing component and the temperature, T_{inlet fluid}, of the fluid input for cooling the component is smaller. For that reason, a small thermal resistance, R_{heat sink}, may be preferable.

A heat sink may have a small thermal resistance, R_{heat sink}, because the heat sink has a complex three-dimensional (3D) structure. In particular, a complex 3D structure may provide a large surface to volume ratio for better transferring heat to a coolant fluid and/or may provide channels that more effectively control the flow of a coolant fluid through the body of the heat sink. Unfortunately, some heat sinks with complex 3D structures can be expensive to manufacture directly via conventional techniques such as metal casting or metal printing. In particular, such heat sinks can be expensive to manufacture as a single solid block. Also, since a heat sink may be subject to thermal stresses during manufacture and/or operation, e.g., some heat sinks with complex 3D structures can warp or undesirably deform during manufacture and/or operation. For these reasons, different methods of manufacture and/or structural design may be useful for heat sinks with complex 3D structures.

Herein, a heat sink is referred to as having a complex 3D structure if the heat sink has an irregular or regular array of channels for controlling the passage of a coolant fluid through the heat sink. In such complex 3D structures, the channels have, at least, some segments that are closed on all sides transverse to a flow direction of the fluid passing through the heat sink. Some embodiments of such heat sinks have a complex array of substantially parallel channels for passing the coolant fluid through the heat sink. The array of channels may provide a high surface area for the exchange of heat between the heat sink and the coolant fluid and/or may improve the mixing of the coolant fluid to enhance the transfer of heat from the heat sink to the coolant fluid.

Herein, a coolant fluid for a heat sink may be a gas, e.g., air or another conventional gas useable for cooling, or may be a liquid, e.g., water or another conventional liquid useable for cooling. The coolant fluid is able to flow through some of the channels of the embodiments of heat sinks with complex 3D structures.

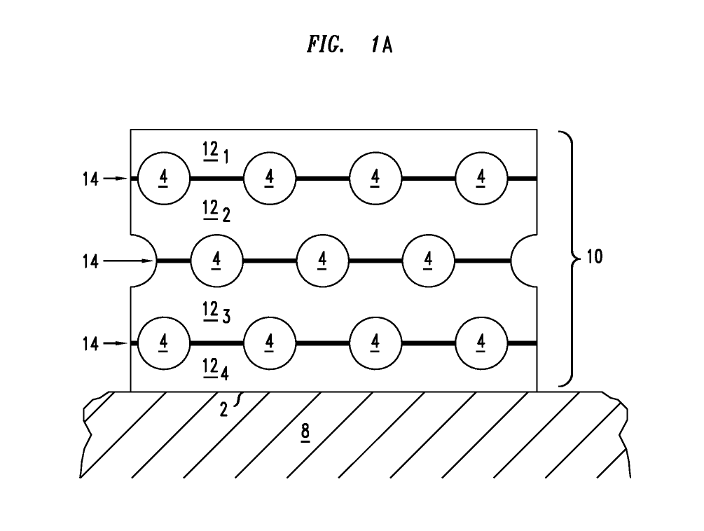

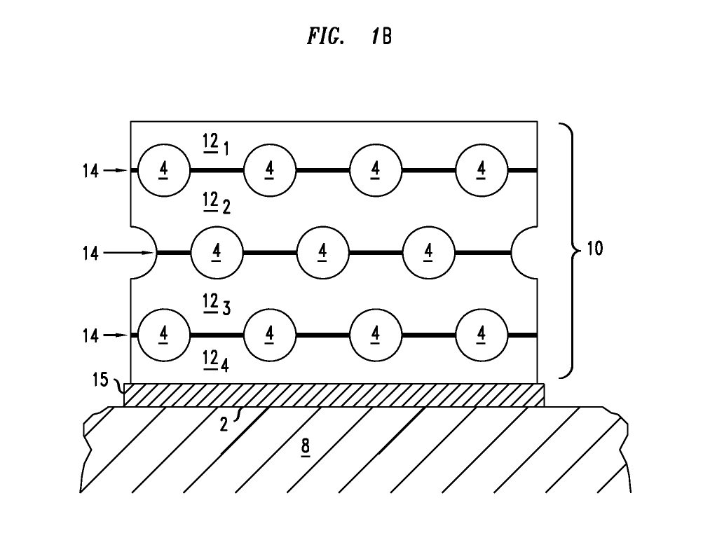

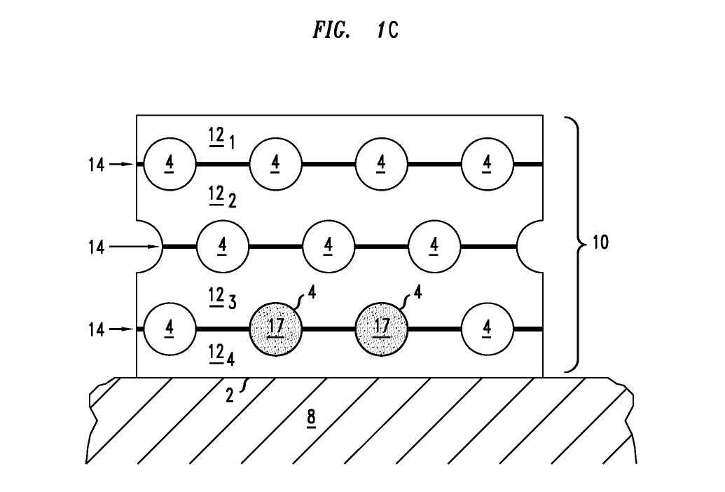

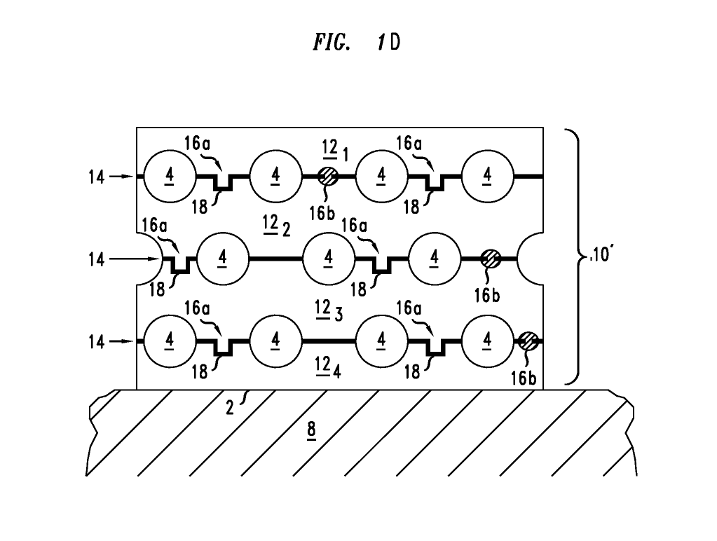

FIGS. 1A-1D schematically illustrate various embodiments of apparatus that include a heat sink 10, 10′ that is located to cool or temperature-stabilize an electronic or optical component or circuit board 8, which internally produces heat during operation. The heat sinks 10, 10′ have complex 3D structures and are examples of laminated heat sinks. The heat sinks 10, 10′ are located to receive heat from a nearby portion of a surface 2 of the electronic or optical component or circuit board 8. In various embodiments, the heat sink 10, 10′ is a segment of a primary path for dissipating heat that is internally generated by the electronic or optical component or circuit board 8 during its operation. For example, the path including the heat sink 10, 10′ may be able to dissipate at least 50%, preferably at least 75%, and more preferably at least 90% of the heat internally produced by the electronic or optical component or circuit board 8 during its ordinary operation.

Each heat sink 10, 10′ includes a stack of N metal layers 12₁, 12₂, . . . 12_{N} with physical interface regions located between the different metal layers 12₁-12_{N}. Herein, a physical interface region has different local physical form than the interior region of the metal layers on each side of the physical interface region. For example, the physical interface region may include surfaces of the bordering metal layers and/or may have a physical weld, braze, or solder joint of the bordering metal layers. In some embodiments, a physical interface material may include a region of a different chemical composition than the bordering metal layers, e.g., a different metal alloy, e.g., a braze or solder material, or a very different chemical composition, e.g., a thermally conductive grease.

While FIGS. 1A-1D illustratively show four metal layers 12₁-12₄, the value of N may be different in other embodiments. The number N is generally greater than or equal to 2 and may be a large integer, e.g., the stack may have greater than 10, 20, 30, 40, 50, or 100 of the metal layers 12₁-12_{N}.

In the illustrative embodiments of FIGS. 1A-1D, the metal layers 12₁-12_{N} are stacked along a direction substantially normal to the nearby facing portion of the surface 2 of the electronic or optical component or circuit board 8, which dissipates heat. That is, the stacking direction of the metal layers 12₁-12_{N} is along the normal to said portion of the surface 2 or is, at least, within 25 degrees of the average normal direction to said portion of the surface 2.

Each heat sink 10, 10′ includes an array of channels 4 through the stack of metal layers 12₁-12_{N}. The channels 4 may be substantially parallel and/or may have segments that are substantially parallel to the nearby surface 2 of the electronic or optical component or circuit board 8. The channels 4 are configured to carry a coolant fluid through the stack of the heat sink 10, 10′. The array of channels 4 may increase the surface area for the transfer of heat from the heat sink 10, 10′ to the flowing coolant fluid and/or may enhance mixing of flowing coolant fluid thereby improving such a transfer of heat. Some pairs of the channels 4 may be connected by transverse openings (not shown). Such openings may enable the coolant fluid from different such pairs of the channels 4 to mix.

Each channel 4 has an inner surface that is formed by portions of more than one of the metal layers 12₁-12_{N} of the stack. In the embodiments of FIGS. 1A-1D, the channels 4 are shaped and located so that their inner surfaces are located between facing ones of the metal layers 12₁-12_{N}. That is, in FIGS. 1A-1D, each exemplary channel 4 has segment in the physical interface region between a facing pair of the metal layers 12₁-12_{N} of the stack. Such a configuration provides one example of how individual planar or deformed embodiments of the metal layers 12₁-12_{N} may be stacked to form the array of the channels 4. Such planar or deformed planar shapes for the individual metal layers 12₁-12_{N} may be formed via inexpensive processes, e.g., conventional processes for stamping metal sheets or extruding metal structures, or other processes for forming metal layers without a step of a subsequent removal of sacrificial layers having nontrivial 3D topologies.

During operation, each heat sink 10, 10′ is positioned along and in thermal contact with a facing portion of a surface 2 of the electronic or optical component or circuit board 8, e.g., an electronic or optical component that internally produces heat during operation.

In some embodiments, the heat sink 10, 10 may be located directly on the heat-dissipating surface 2 of the component or circuit board 8 as illustrated, e.g., in FIGS. 1A, 1C, and 1D.

Alternately, a thermally conductive interface material may be located between the heat sink 10, 10′ and facing portion of the heat-dissipating surface 2 of the component or circuit board 8. For example, thermally conductive interface material may include thermally conductive grease.

Alternately, as illustrated, e.g., in FIG. 1B, the heat sink 10, 10′ may be located on a heat-spreader 15, which is, in turn, located on the facing portion of the heat-dissipating surface 2 of the component or circuit board 8. Such a heat-spreader 15 may spread heat produced at a local hot spot of the component or circuit board 8 along the facing surface of the heat sink 10, 10′ so that the volume of the heat sink 10, 10′ can more effectively dissipate said heat. The heat spreader 15 may be or include, e.g., a copper plate or block, one or more heat pipes, a metal block with one or more heat pipes therein, or a vapor chamber to lateral spread the heat along the direction of facing portion of the surface 2.

Alternatively, as illustrated, e.g., in FIG. 1C, the heat sink 10, 10′ may include one or more heat pipes 17 in one or more of the channel(s) 4 of the heat sink 10, 10′. Such heat pipe(s) 17 can also laterally spread heat in heat sink 10, 10′ when the heat is internally produced at a nearby local hot spot of the component or circuit board 8. Again, such active spreading can improve the effectiveness of the heat sink 10, 10′ at dissipating said heat. The one or more heat pipes 17 may entirely traverse a length of the heat sink 10, 10′ along a direction parallel to the surface 2 and/or may only traverse a portion of said length of the heat sink 10, 10′. The one or more heat pipes 17 may be located in one(s) of the channel(s) that is(are) open at both ends or is(are) open at only one end and may or may not block said one(s) of the channel(s) to the flow of a fluid around the outside of heat pipe(s) 17.

In the embodiments of FIGS. 1A, 1C, and 1D, the heat sink 10, 10′ may be mechanically bonded to the component or circuit board 8. For example, the heat sink 10, 10′ may be brazed, welded, soldered, or screwed to the facing portion of the surface 2 of the component or circuit board 8. Alternatively, in the embodiment of FIG. 1B, the heat sink 10, 10′ may be brazed, welded, soldered, or screwed to a portion of a surface of the heat spreader 15, which is itself brazed, welded, soldered or screwed to the adjacent portion of the heat-dissipating surface 2 of the component or circuit board 8. In the various embodiments of FIGS. 1A-1D, the heat sink 10, 10′ may include a thicker and/or wider metal base (not shown), which provides region(s) and/or smooth surface(s) for the mechanically fixing and suitable thermal coupling, e.g., via braze, solder, or screws, to a surface of the heat spreader 15 and/or the facing portion of the heat-dissipating surface 2 of the component or circuit board 8.

Referring to FIGS. 1A-1D, in some embodiments of the heat sinks 10, 10′, the metal layers 12₁-12_{N} may have one or more openings substantially vertically passing there through. For example, such openings may transversely connect pairs of the channels 4 to enable the mixing of the coolant fluid flowing in those channels 4.

Referring to FIGS. 1A-1D, the heat sinks 10, 10′ may optionally include thermal interface material 14 between neighboring ones of the metal layers 12₁-12_{N}, e.g., to improve heat conduction between the metal layers 12₁-12_{N} of the heat sink's stack. The thermal interface material may be any thermally conductive material that is known to be useful for improving heat conduction between adjacent metal members. In some embodiments, the thermal interface material may be a solder or a metal or alloy braze that mechanically joins together neighboring ones of the metal layers 12₁-12_{N}. In other embodiments, the thermal interface material may be conventional thermally conductive grease.

Referring to FIG. 1D, neighboring ones of the metal layers 12₁-12_{N} of the heat sink 10′ may be mechanically aligned and/or held together by metal structures located at or near physical interface regions between the metal layers 12₁-12_{N}. For example, the metal structures may include protrusions 16a that snugly fit or snap into holes 18 in the facing metal layers 12₁-12_{N}. Alternately or additionally, the metal structures may be separate structures 16b that mechanically align and/or fix together the neighboring ones of the metal layers 12₁-12_{N}. Such separate structures 16b may be pins, screws or rivet-shaped structures.

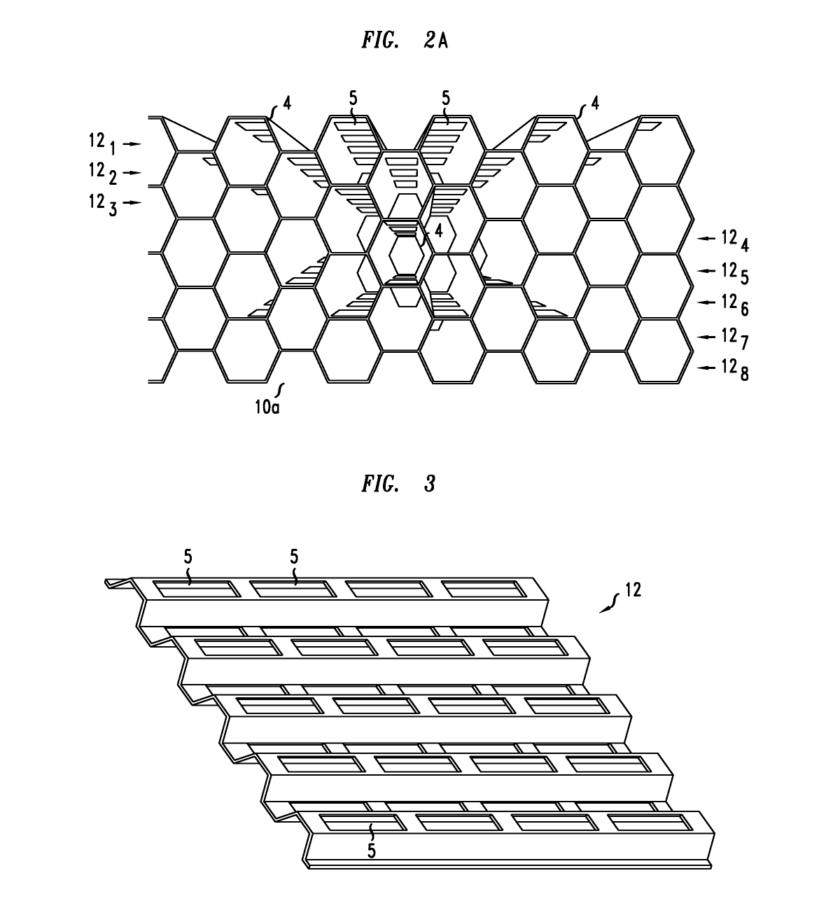

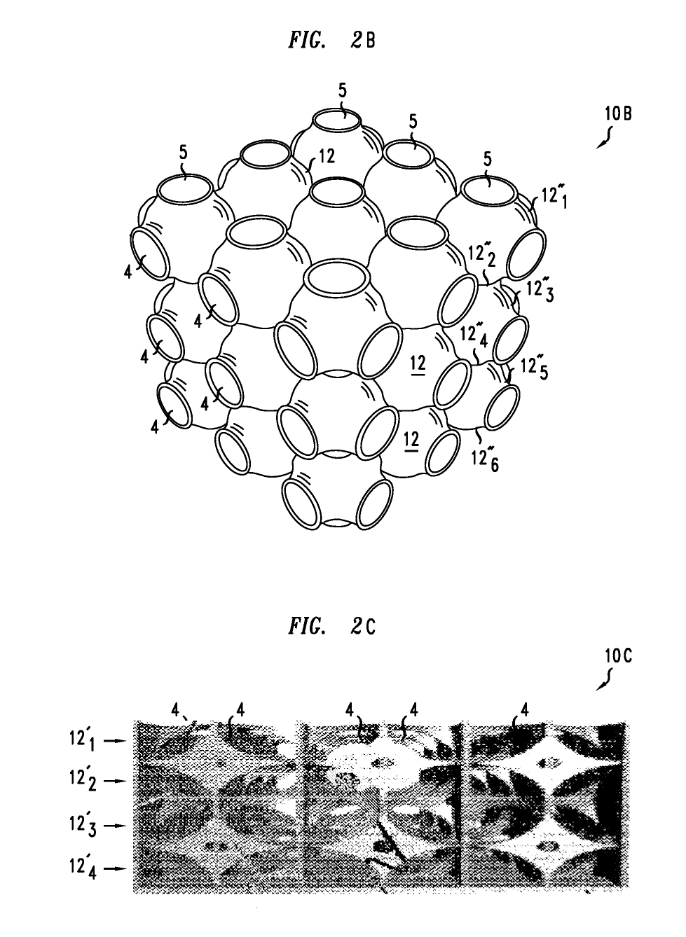

FIGS. 2A, 2B, and 2C illustrate examples of heat sinks 10A, 10B, 10C with respective honeycomb, Schwarz-P, and foam-like structures, e.g., specific embodiments of the heat sinks 10, 10′ of FIGS. 1A-1D.

Each heat sink 10A, 10B, 10C includes a multi-layered stack whose cross section forms a two-dimensional (2D) lattice. For example, the 2D lattice may be hexagonal as in FIG. 2A or rectangular or square as in FIGS. 2B-2C. In the heat sinks 10A, 10B, 10C, the channels 4 are substantially parallel and have cross-sectional shapes that are hexagonal in FIG. 2A, circular in FIG. 2B, and irregular-shaped in FIG. 2C. In the heat sinks 10A, 10B, 10C, adjacent ones of the channels 4 may be interconnected by openings 5 in side walls thereof. The openings 5 produce mixing of flowing coolant fluid between different ones of the channels 4. The openings 5 are slot-shaped in FIG. 2A; are circular or elliptical in FIG. 2B; and are irregularly shaped or absent in FIG. 2C.

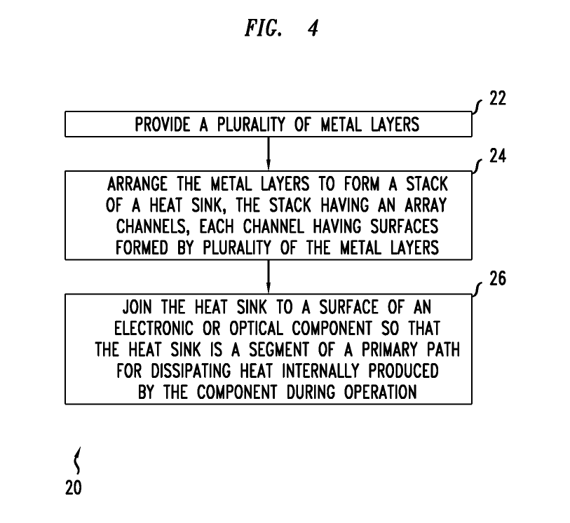

Referring again to FIG. 2A, the heat sink 10A may be formed of substantially identical individual layers 12₁-12₈ whose form 12 is shown in FIG. 3. The layer 12 may be used to construct each of the metal layers 12₁-12₈ of the heat sink 10A, because the layer 12 is half of a horizontal honeycomb. The layer 12 is flipped in alternate ones of the metal layers 12₁-12₈ of the stack that forms the heat sink 10A.

In a similar manner, some other laminated heat sinks, e.g., heat sink 10B of FIG. 2B, may be formed, e.g., of a stack of metal layers 12″₁-12″₆ of a single form. In particular, such metal layers 12″₁-12″₆ can form a portion of the heat sink about a local symmetry or reflection plane.

Referring to FIG. 2C, the heat sink 10C includes a rectangular or cubic array that is formed of a stack of metal layers 12′₁-12′₄. The stack includes approximately parallel and optionally interconnected channels 4 with irregular interior shapes and/or abrupt protrusions along walls thereof. The inclusion of irregular or abrupt structures inside the channels 4 can increase mixing of the coolant fluid flowing through the heat sink 10C and/or provide mixing of laminar regions of such flowing coolant fluid thereby lowering the thermal resistance of the heat sink 10C.

In other embodiments, the heat sinks 10, 10′ of FIGS. 1A-1D may have other geometries, which are complex 3D structures, and/or may be formed of laminated layers having other shapes.

In some embodiments, the metal layers of the laminated heat sinks with complex 3D structures may be made with two or more different patterns, e.g., patterns A and B or patterns A, B, C, D, etc. In such laminated heat sinks, the stack may sequentially alternate between the metal layers with the different patterns to produce a selected complex 3D structure. Indeed, the stack may include a sequence of the metal sheets in which the pattern continues to change over a series of many metal layers.

FIG. 4 is a flow chart illustrating a method 20 for manufacturing a heat sink with a complex 3D structure, e.g., the laminated heat sinks 10, 10′, 10A, 10B, 10C of FIGS. 1A, 1B, 1C, 1D, 2A, 2B, and 2C.

The method 20 includes providing separate metal layers for forming a complex 3D structure of the heat sink (step 22). The provided metal layers may be, e.g., the metal layers 12₁-12_{N}, 12 of FIGS. 1A, 1B, 1C, 1D, 2A, 2B, and 2C.

The providing step 22 may optionally included forming the individual metal layers via a conventional stamping process. The stamping process may include stamping a metal sheet with a first stamp die to punch one or more openings therein. Some of the openings may provide, e.g., interconnections between the fluid carrying channels of the array in the final heat sink, e.g., the openings 5 of FIGS. 2A-2B and 3. In some embodiments, some of the openings or portions thereof may form segments of the fluid transporting channels of the array in the final heat sink (not shown). The stamping process may further include stamping the metal sheets with such openings with one or more other stamp dies to deform the metal sheets thereby producing folds and/or bends therein, e.g., the bends or folds shown in FIG. 3. To facilitate such a stamping process, the metal layers may be formed of a metal alloy that is known to be adapted to stamping processes that produce fold(s) and/or bend(s).

The providing step 22 may optionally include manufacturing the individual metal layers via another conventional process, e.g., metal extrusion or laser machining.

The method 20 includes arranging and mechanically fixing the metal layers from the providing step 22 to form a stack of the heat sink, e.g., as shown in FIGS. 1A-1D and 2A-2C (step 24). In the stack, physical interface regions are located between the metal layers. Also, the stack includes an array of channels that are capable of carrying a coolant fluid through the stack, e.g., the channels 4 of FIGS. 1A-1D. Each channel has a lateral surface that is formed by portions of more than one of the metal layers of the stack.

In some embodiments, each channel may have a segment formed in an interface region between a facing pair of the metal layers of the stack.

In some embodiments, the arranging and fixing step 24 may involve aligning successive ones of the metal layers of the stack differently to produce a complex 3D structure therein, e.g., for the array of channels. For example said successive ones of the metal layers may be relatively shifted and/or may be relatively flipped or inverted during the stacking step 24.

In some embodiments, the arranging and fixing step 24 may include placing a thermally conductive interface material between neighboring pairs of the metal layers in the stack, i.e., prior to forming the portion of the stack in which such a pair of the metal layers are neighbors. In example embodiments, the thermally conductive interface material may be a solder or a metal or alloy braze, which is melted between the metal layers of a facing pair during the arranging and fixing step 24 or alternatively, the thermally conductive interface material may be a thermally conductive grease.

In some embodiments, the stacking step 24 may include mechanically joining together neighboring pairs of the metal layers, e.g., rigidly fixing together each pair of said metal layers while the metal layers are being relatively positioned in the stack. For example, the mechanically joining may involve soldering, brazing, or welding the neighboring metal layers together during the arranging and fixing step 24. The mechanically joining may alternatively or also involve tightly inserting protrusion(s) from one of metal layer into hole(s) in one of the facing metal layers in the stack. For example the mechanically joining may involve positioning separate mechanical joiner(s), e.g., pins or rivets, into two facing metal layers of the stack to rigidly fix together and/or rigidly relatively align the two facing metal layers. Alternatively, the mechanically joining may involve placing a clamp around the whole stack of relatively positioned metal layers and adjusting the clamp to compressively and rigidly fix the metal layers of the stack together.

The method 20 may optionally include bonding the heat sink to an element from which heat is to be dissipated by the heat sink during operation (step 26). The bonding step 26 typically produces a thermal connection to a facing portion of a heat-dissipating surface of the element so that the heat sink may function as a segment of a primary path for dissipating heat that the element produces during operation. For example, the thermal connection through the heat sink may dissipate at least 50%, preferably at least 75%, and more preferably at least 90% of the heat internally produced by the element during its ordinary operation.

In some examples, the heat sink may be located adjacent to the facing portion of the surface of the element so that the metal layers of the heat sink are stacked along a direction that is approximately tangent to that portion of the surface. Locating the heat sink in such a manner may lower its thermal resistance, because heat conduction can occur through the heat sink along a direction that is about normal to that portion of the surface of the heat-producing element without traversing physical interface regions between the metal layers of the heat sink. Such a heat sink may be less expensive to make, because the coolant fluid carrying channels of the heat sink may be produced by stamping holes through individual ones of the metal layers and then, stacking the metal layers so that the holes form sections of the array of the channels in the final heat sink. That is, the stack may be formed such that each metal layer thereof itself includes a segment of the channels that carry coolant fluid through the stack.

Alternately, the heat sink may be located to have its metal layers stacked in a direction approximately normal, i.e., substantially normal, to that portion of the surface of the element facing the heat sink. For example, the direction of stacking may be along the normal to that portion of the surface or within 25 degrees of the average direction of normal vectors to said portion of the surface.

In some embodiments, the bonding step 26 includes producing a configuration in which the heat sink is bonded to the electronic or optical element that internally produces heat during its operation, and the element is fixed to a circuit board or card, e.g., wherein the circuit board or card is configured to fix into a rack or shelf of circuit boards.

The bonding step 26 may include, e.g., mechanically fixing a metal base portion of the heat sink to the element that produces heat to be dissipated via the heat sink. For example, the metal base portion may have a wider footprint, be thicker, and/or have smoother surface(s), which facilitate its mechanical fixation to the heat-dissipating element via fasteners such as screws or nuts and bolts.

Alternately, the bonding step 26 may include mechanically fixing a heat spreader between the heat sink and a heat-dissipating portion of the surface of the element, e.g., to laterally spread heat produced at a local hot spot of the element. The bonding may include clamping the heat sink to the element so that the heat sink forms a segment of a primary path for the dissipation of heat produced internally by the element during its ordinary operation, e.g., to be a segment of a path that dissipates at least 50%, preferably at least 75%, and more preferably at least 90% of said internally produced heat.

The Detailed Description of the Illustrative Embodiments and drawings merely illustrate the principles of the inventions. It will thus be appreciated that those skilled in the art will be able to devise various arrangements that, although not explicitly described or shown herein, embody the principles of the inventions and are included within the claimed inventions. Furthermore, all examples recited herein are principally intended to be only for pedagogical purposes to aid in understanding the principles of the inventions and concepts contributed by the inventor to furthering the art, and are to be construed as being without limitation to such specifically recited examples and conditions. Moreover, all statements herein reciting principles, aspects, and embodiments of the inventions, as well as specific examples thereof, are intended to encompass equivalents thereof.

What is claimed is:

1. An apparatus, comprising:
a heat sink with a complex 3D structure, the heat sink including a stack of metal layers, the metal layers being mechanically connected together and separated by physical interface regions; and
wherein the stack has an array of channels for carrying fluid through the stack; and
wherein each channel of the array has a lateral surface formed by portions of more than one of the metal layers.

2. The apparatus of claim 1, wherein each channel of the array includes a segment in the physical interface region between a pair of the metal layers of the stack.

3. The apparatus of claim 1, wherein some of the metal layers include openings that interconnect pairs of the channels.

4. The apparatus of claim 1, wherein some of the metal layers of the stack are brazed, welded, or soldered together.

5. The apparatus of claim 1, further comprising thermally conductive grease located between neighboring ones of the metal layers.

6. The apparatus of claim 1, further including a heat pipe, a segment of the heat pipe being located in one of the channels.

7. The apparatus of claim 1, further comprising:
an electronic or optical component configured to internally produce heat during operation, a first surface of the heat sink facing and being in thermal contact with a portion of a second surface of the electronic or optical component.

8. The apparatus of claim 7, wherein the metal layers are stacked along a direction substantially normal to the portion of the second surface.

9. The apparatus of claim 7, wherein the some of the layers include openings that interconnect pairs of the channels.

10. The apparatus of claim 7, wherein some of the metal layers of the stack are brazed, welded, or soldered together.

11. The apparatus of claim 7, further including a circuit board, the electronic or optical component being mechanically fixed to the circuit board.

12. The apparatus of claim 7, further comprising one or more heat pipes or a vapor chamber located between the electronic or optical component and the heat sink.

13. The apparatus of claim 7, further including a heat pipe, a segment of the heat pipe being located in one of the channels.

14. A method of fabrication, comprising:
providing a plurality of metal layers; and
arranging and fixing the metal layers to form a stack of a heat sink with a complex 3D structure, the stack having physical interface regions located between the metal layers and having an array of channels for carrying fluid through the stack, each channel having a lateral surface formed by portions of more than one of the metal layers.

15. The method of claim 14, wherein each channel includes a segment in the physical interface region between a pair of the metal layers of the stack.

16. The method of claim 14, wherein some of the provided metal layers include openings, each opening interconnecting a pair of the channels in the heat sink.

17. The method of claim 14, further comprising mechanically and thermally joining the heat sink to a portion of a surface of an electronic or optical component such that the heat sink forms segment of a primary path for dissipating heat internally generated by the electronic or optical component during operation thereof.

18. The method of claim 17, wherein the joining causes the metal layers to be stacked along a direction substantially normal to the portion of the surface of the electronic or optical component.

19. The method of claim 17, further comprising a circuit board, the electronic or optical component being mechanically fixed to the circuit board.

20. The method of claim 17, wherein the mechanically and thermally joining includes fixing a one or more heat pipes or a vapor chamber between the heat sink and the portion of the surface of the electronic or optical component.
